(19) United States
(12) Patent Application Publication
(10) Pub. No.: US 2024/0379707 A1
(43) Pub. Date: Nov. 14, 2024

(54) SENSING PACKAGE STRUCTURE

(71) Applicants: LITE-ON TECHNOLOGY CORPORATION, TAIPEI CITY (TW); Lite-On Singapore Pte. Ltd., Singapore (SG)

(72) Inventors: I-CHEN CHIEN, Keelung City (TW); WEI JIAN JENSON NEO, Singapore (SG)

(21) Appl. No.: 18/411,227

(22) Filed: Jan. 12, 2024

(30) Foreign Application Priority Data
May 12, 2023 (CN) 202321131611.0

(51) Int. Cl. H01L 27/146

(52) U.S. Cl. CPC H01L 27/14629; H01L 27/14618; H01L 27/14649

(57) ABSTRACT

A sensing package structure includes a substrate, a sensor, an optical element, and a first blocking layer. The sensor is disposed on the substrate. The optical element is disposed above the sensor. The first blocking layer is disposed on the optical element. The first blocking layer has a first opening, and an aperture of the first opening is greater than a thickness of the optical element. A radiation that enters the first opening passes through the optical element and is received by the sensor.

### CROSS-REFERENCE TO RELATED PATENT APPLICATION

This application claims the benefit of priority to China Patent Application No. 202321131611.0, filed on May 12, 2023, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a sensing package structure, and more particularly to a sensing package structure that can have a reduced overall size.

### BACKGROUND OF THE DISCLOSURE

In the related art, a temperature sensor has a metal cover for covering a chip package structure, and the metal cover is designed to have an opening to accommodate an optical filter. A radiation generated by an object in the external environment will be received by the chip package structure inside the metal cover through the optical filter disposed in the opening.

The metal cover is firm but large in size. For example, a total height of the metal cover and optical filter of the existing temperature sensor exceeds 2 mm. Therefore, the existing temperature sensor is easily limited by the size of the metal cover and is difficult to comply with the thin, lightweight, and miniaturized design trend required in the market. In addition, the metal cover and the optical filter require multiple processes such as stamping, ultrasonic welding, and electroplating during the manufacturing process, which is complex and costly.

Therefore, how to improve structural design to reduce the overall size of the temperature sensor and overcome the above-mentioned inadequacy has become an important issue to be addressed in the technical field.

### SUMMARY OF THE DISCLOSURE

In response to the above-referenced technical inadequacies, the present disclosure provides a sensing package structure.

In one aspect, the present disclosure is to provide a sensing package structure. The sensing package structure includes a substrate, a sensor, an optical element, and a first blocking layer. The sensor is disposed on the substrate. The optical element is disposed above the sensor. The first blocking layer is disposed on the optical element. The first blocking layer has a first opening, and an aperture of the first opening is greater than a thickness of the optical element. A radiation that enters the first opening passes through the optical element and is received by the sensor.

In another aspect, the present disclosure is to provide a sensing package structure. The sensing package structure includes a substrate, a sensor, and an optical element. The sensor is disposed on the substrate. The sensor has a sensing region for receiving an infrared. The optical element is disposed above the sensor. The optical element includes a carrier, a first light-permeable layer, and a second light-permeable layer. The carrier has a first surface and a second surface that are opposite to each other. The first light-permeable layer is disposed on the first surface. A first blocking layer is disposed on the first light-permeable layer. The second light-permeable layer is disposed on the second surface. A width of the first light-permeable layer is smaller than a width of the second light-permeable layer. The first light-permeable layer faces the sensing region.

Therefore, in the sensing package structure provided by the present disclosure, by virtue of “the first blocking layer being disposed on the optical element, the first blocking layer having a first opening, and an aperture of the first opening being greater than a thickness of the optical element,” “a radiation that enters the first opening passing through the optical element and being received by the sensor,” and “a width of the first light-permeable layer being smaller than a width of the second light-permeable layer, and the first light-permeable layer corresponding to the sensing region,” the overall size of the sensing package structure can be reduced and the field of view of the sensor package can be adjusted.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a sensing package structure according to the present disclosure;

FIG. 2 is a schematic side view of a sensing package structure according to a first embodiment of the present disclosure;

FIG. 3 is a schematic view showing a detection model of the sensing package structure according to the first embodiment of the present disclosure;

FIG. 4 is a schematic view of a first implementation of an optical element of the sensing package structure according to the first embodiment of the present disclosure;

FIG. 5 is a curve diagram showing transmittance and reflectivity of each element of the sensing package structure for radiations having different wavelengths according to the present disclosure;

FIG. 6 is a schematic view of a second implementation of the optical element of the sensing package structure according to the first embodiment of the present disclosure;

FIG. 7 is a schematic view of a third implementation of the optical element of the sensing package structure according to the first embodiment of the present disclosure;

FIG. 8 is a schematic view of a fourth implementation of the optical element of the sensing package structure according to the first embodiment of the present disclosure;

FIG. 9 is a schematic view showing a detection model of a sensing package structure according to a second embodiment of the present disclosure;

FIG. 10 is a schematic view of an optical element of the sensing package structure according to the second embodiment of the present disclosure;

FIG. 11 is a schematic view showing a detection model of a sensing package structure according to a third embodiment of the present disclosure; and

FIG. 12 is a schematic view of an optical element of a sensing package structure according to a fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

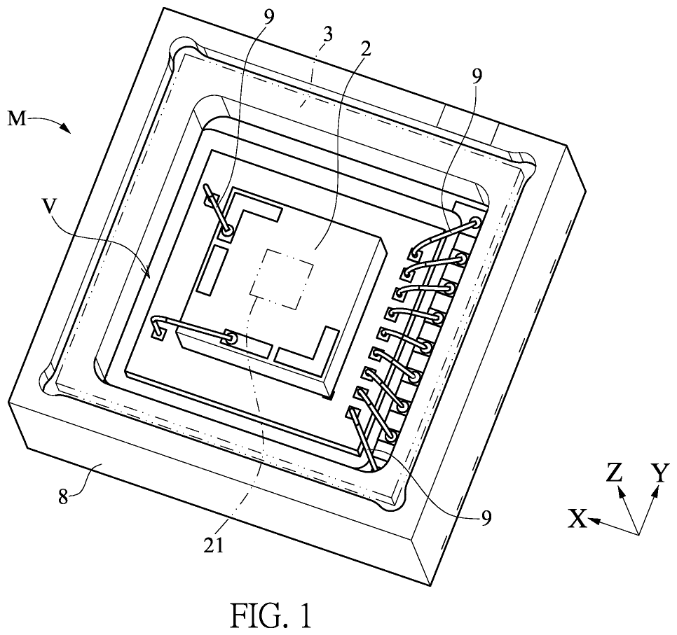

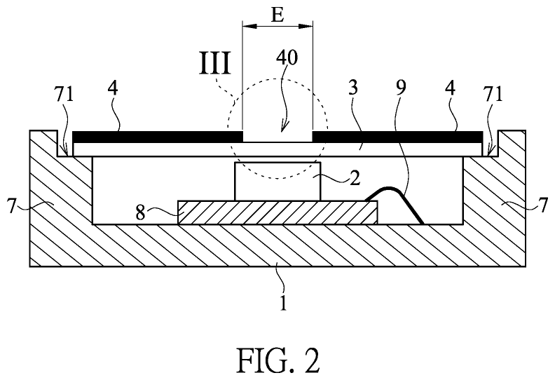

Referring to FIG. 1 and FIG. 2, FIG. 1 is a schematic perspective view of a sensing package structure according to the present disclosure, and FIG. 2 is a schematic side view of a sensing package structure according to a first embodiment of the present disclosure. The present disclosure provides a sensing package structure M that includes a substrate 1, a sensor 2, and an optical element 3. The sensor 2 is disposed on the substrate 1. The optical element 3 is disposed on the substrate 2 and located above the sensor 2. The sensing package structure M further includes a wall 7. The wall 7 is vertically connected to the substrate 1, and the wall 7 and the substrate 1 jointly form a cavity V. The wall 7 has a stepped portion 71. The sensor 2 is disposed in the cavity V, and the optical element 3 is disposed on the stepped portion 71. Therefore, the wall 7 surrounds the substrate 1, the sensor 2, and the optical element 3. It is worth mentioning that, the stepped portion 71 can limit a position of the optical element 3. In addition, the sensing package structure M further includes an integrated circuit (IC) component 8 such as an electronic component for sensing an ambient temperature or converting a signal (e.g., converting an analog signal into a digital signal). The IC component 8 can be located under the sensor 2 (as shown in FIG. 2) or next to the sensor 2, but the present disclosure is not limited thereto. In addition, the IC component 8 is an optional component. In other words, the IC component 8 can be disposed outside the sensing package structure M, that is, the IC component 8 is not a part of the sensing package structure M. Moreover, the sensing package structure M further includes a plurality of metal wires 9. One or more of the metal wires 9 is connected to the sensor 2 and the IC component 8. Remaining ones of the metal wires 9 are connected to the substrate 1 and the IC component 8, and are electrically connected to conductive pads (not shown in the figures) located on a bottom of the substrate 1 through conductive vias (not shown in the figures). Therefore, the sensing package structure M can be connected to external electronic components (not shown in the figures) through the conductive pads, and the sensor 2 can be electrically connected to the external electronic components.

For example, the substrate 1 can be made of ceramic. The sensor 2 can be an optical sensing element. A surface of the sensor 2 has a sensing region 21 for sensing a thermal radiation that is present in the environment or emitted outward from objects. Furthermore, the thermal radiation can be a radiation having a wavelength that ranges in a specific band, such as an infrared which ranges from 760 nm to 1 mm. The optical element 3 has the capability of filtering, and can block or filter radiations in one or more wavelengths. The sensing package structure M provided by the present disclosure is a temperature sensor for temperature sensing, and can sense a middle-wavelength infrared (MWIR) or a long-wavelength infrared (LWIR). The sensing package structure M can sense a radiation having a wavelength range of from 5.5 μm to 14 μm, but the present disclosure is not limited thereto.

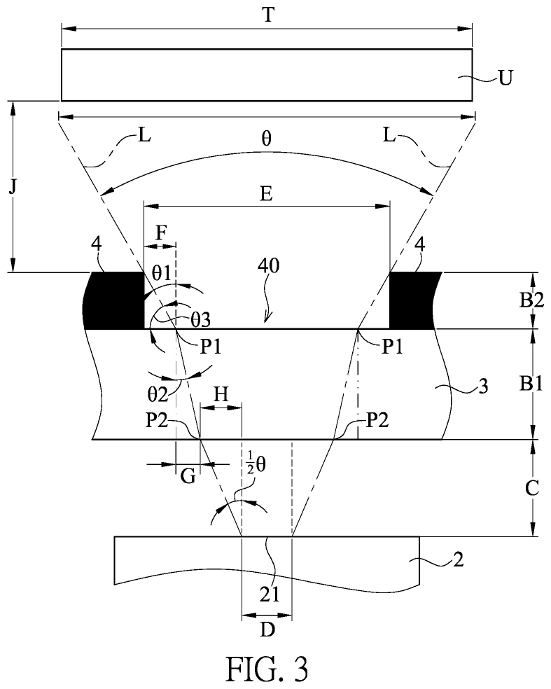

Referring to FIG. 2 and FIG. 3, FIG. 3 is a schematic view showing a detection model of the sensing package structure according to the first embodiment of the present disclosure. The sensing package structure M further includes a first blocking layer 4, and the first blocking layer 4 is disposed on the optical element 3. The first blocking layer 4 has a first opening 40, and a position of the first opening 40 faces the sensing region 21 of the sensor 2. An aperture E of the first opening 40 is greater than a thickness B1 of the optical element 3. The first blocking layer 4 is made of an opaque material, such as a black matrix resist or a black colloid. For example, the opaque material has low transmittance for the middle-wavelength infrared, but the present disclosure is not limited thereto. Therefore, the radiation generated by a to-be-detected object passes through the first opening 40 and the optical element 3, and is then received by the sensor 2. Comparing with the related art, the sensing package structure M provided by the present disclosure does not require a metal cover. Instead, the overall size of the sensing package structure M can be reduced by the optical element 3 being directly disposed on the wall 7 and the first opening 40 being formed on the first blocking layer 4 for light to pass through the first opening 40.

In general, the sensing package structure M has a detectable field of view (FOV). The greater the FOV is, the shorter a detectable distance of the sensing package structure M is; the smaller the FOV is, the longer the detectable distance of the sensing package structure M is. For example, if the FOV is 175 degrees, the detectable distance of the sensing package structure M is about 1 m; if the FOV is 124 degrees, the detectable distance of the sensing package structure M is about 2 m. Furthermore, parameters that affect the FOV are internal structural dimensions of the sensing package structure M, including but not limited to the aperture E of the first opening 40, the size of the sensor 2, a thickness B2 of the first blocking layer 4, and a distance between the sensing region 21 of the sensor 2 and the optical element 3 (referred to as a predetermined vertical distance C). Therefore, the FOV of the sensing package structure M can be adjusted by changing the internal structural dimensions of the sensing package structure M to obtain an appropriate detectable distance.

For example, the greater the size (e.g., the height) of the sensor 2 is, the smaller the FOV is; the smaller the size of the sensor 2 is, the greater the FOV is. The greater the aperture E of the first opening 40 is, the greater the FOV is; the smaller the aperture E of the first opening 40 is, the smaller the FOV is. The greater the thickness B2 of the first blocking layer 4 is, the smaller the FOV is; the smaller the thickness B2 of the first blocking layer 4 is, the greater the FOV is.

The sensing package structure M provided by the present disclosure can also calculate a setting value of the FOV of the sensing packaging structure M based on the required detection distance, and the internal structural dimensions of the sensing packaging structure M can be deduced from the setting value. FIG. 3 further shows other internal structural dimensions of the sensing package structure M. As shown in FIG. 3, the sensor 2 has a sensing angle θ, and the sensing angle θ represents the FOV. An infrared L generated by a to-be-detected object U enters the optical element 3 at an incident angle θ1 and passes through the optical element 3 at a refraction angle θ2. The sensing angle θ is twice the incident angle θ1. An incident position P1 where the infrared L enters the optical element 3 is separated from an exit position P2 where the infrared L is emitted from the optical element 3 by a first horizontal distance G, and the first horizontal distance G meets the following relation:

$$G = B 1 \times tan ( θ2 ) ; \qquad equation ( 1 )$$

where G is the first horizontal distance, B1 is the thickness of the optical element 3, and θ2 is the refraction angle. It should be noted that the infrared L enters the optical element 3 from the external environment (i.e., the medium is air). Therefore, the refraction angle θ2 can be calculated through Snell Law after obtaining the incident angle θ1 and refractive indexes of the optical element 3 and the air.

The sensing region 21 of the sensor 2 is configured to receive the infrared L. The sensing region 21 faces the first opening 40, the exit position P2 where the infrared L is emitted from the optical element 3 is separated from the sensing region 21 by a second horizontal distance H, and the second horizontal distance H and the predetermined vertical distance C meet the following relation:

$$H = C \times tan ( θ / 2 ) \qquad equation ( 2 )$$

where H is the second horizontal distance, C is the predetermined vertical distance, and θ is the sensing angle.

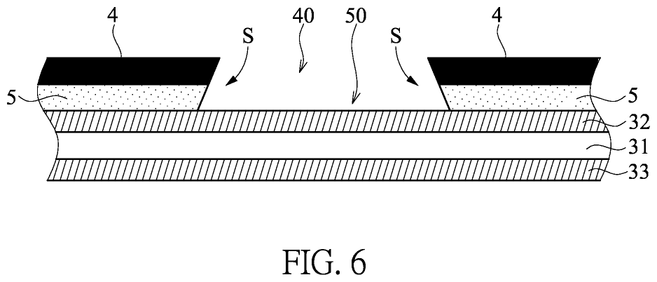

A portion where the first opening 40 is formed on the first blocking layer 4 forms a cross section S (refer to FIG. 6), the cross section S is separated from the incident position P1 where the infrared L enters the optical element 3 by a third horizontal distance F, and the third horizontal distance F meets the following relation:

$$F = B 2 / tan ( θ3 ) ; \qquad equation ( 3 )$$

where F is the third horizontal distance, B2 is the thickness of the first blocking layer 4, and θ3 is an alternate interior angle of the incident angle θ1.

In addition, the aperture E of the first opening 40 meets the following relation:

$$E = 2 F + 2 G + 2 H + D ; \qquad equation ( 4 )$$

where E is the aperture of the first opening 40, F is the third horizontal distance, G is the first horizontal distance, H is the second horizontal distance, and D is a width of the sensing region 21.

For example, when the sensing package structure M senses the temperature of the to-be-detected object U, the FOV set by the sensing package structure M is 120 degrees (i.e., the sensing angle θ of the sensor 2 is set to be 120 degrees), the incident angle θ1 of infrared L is 60 degrees, and the refraction angle θ2 is 12.5 degrees. The thickness B1 of the optical element 3 is 0.25 mm, the thickness B2 of the first blocking layer 4 is 0.05 mm, the predetermined vertical distance C is 0.136 mm, the width D of the sensing region 21 is 0.75 mm, and the aperture E of the first opening 40 is unknown. The first horizontal distance G, the second horizontal distance H, and the third horizontal distance F are calculated according to the equations (1) to (3):

$$\begin{matrix}G = B 1 \times tan ( θ2 ) = 0.0 \; 554 mm ; \\ H = C \times tan ( θ / 2 ) = 0.2 \; 356 mm ; \\ F = B 2 / tan ( θ3 ) = 0.0 \; 866 mm .\end{matrix}$$

Then, the aperture E of the first opening 40 is calculated according to the equation (4):

$$E = 2 F + 2 G + 2 H + D = 1.5052 mm .$$

In other words, when the FOV of the sensing package structure M is set to be 120 degrees, the aperture E of the first opening 40 inside the sensing package structure M needs to be adjusted to be 1.5052 mm.

Moreover, a detection distance J of the sensing package structure M meets the following relation:

$$J = ( ( T - ( E - 2 F ) ) / ( 2 \times tan ( θ1 ) ) ) - B 2 ; \qquad equation ( 5 )$$

where J is the detection distance of the sensing package structure M (i.e., a distance between the sensing package structure M and the to-be-detected object U), and T is the size of the to-be-detected object U (e.g., a length, a width, or a height).

Therefore, after the size T of the to-be-detected object U is obtained and the aperture E of the first opening 40 is calculated from the above equation (4), the detection distance J can then be calculated from the equation (5). However, the aforementioned details are disclosed for exemplary purposes only, and are not meant to limit the scope of the present disclosure. In other embodiments, the detection distance J required for the sensing package structure M can also be set first, and then the required FOV and internal structural dimensions (e.g., the aperture E of the first opening 40) are obtained according to the equations (1) to (5).

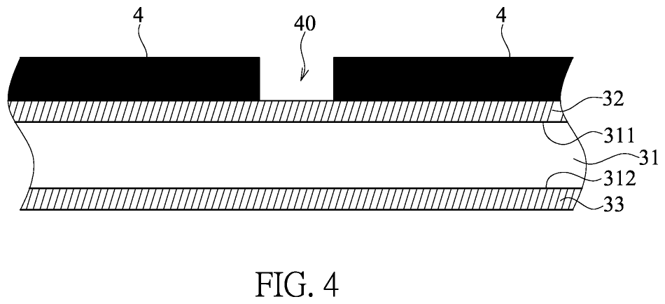

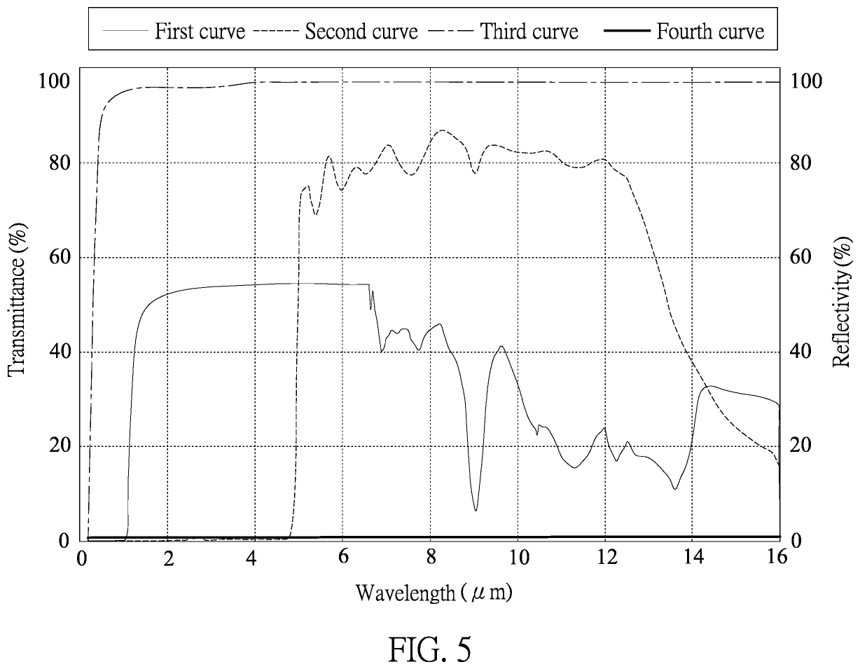

Referring to FIG. 4 and FIG. 5, FIG. 4 is a schematic view of a first implementation of an optical element of the sensing package structure according to the first embodiment of the present disclosure, and FIG. 5 is a curve diagram showing transmittance and reflectivity of each element of the sensing package structure for radiations having different wavelengths according to the present disclosure. The optical element 3 includes a carrier 31, a first light-permeable layer 32, and a second light-permeable layer 33. The carrier 31 has a first surface 311 and a second surface 312 that are opposite to each other. The first light-permeable layer 32 is disposed on the first surface 311, and the second light-permeable layer 33 is disposed on the second surface 312. The first blocking layer 4 is disposed on the first light-permeable layer 32. In FIG. 5, a first curve represents the carrier 31, a second curve represents the light-permeable layer structure (i.e., the first light-permeable layer 32 and the second light-permeable layer 33), a third curve represents a reflective layer 5 (which can be referred to in FIGS. 6 to 8), and a fourth curve represents the first blocking layer 4. It can be seen from FIG. 5 that the carrier 31 is less likely to be passed by the middle-wavelength and long-wavelength infrareds. Therefore, the transmittance of the optical element 3 can be improved (i.e., the amount of the middle-wavelength and long-wavelength infrareds passing through the optical element 3 can be increased) through the arrangement of the light-permeable layer structure (i.e., the first light-permeable layer 32 and the second light-permeable layer 33 are likely to be passed by the middle-wavelength and long-wavelength infrareds), especially for the middle-wavelength and long-wavelength infrareds having a wavelength range of from 5.5 μm to 14 μm and being sensed by the sensing package structure M. Therefore, the transmittance of the carrier 31 can be improved through the light-permeable layer structure (the first light-permeable layer 32 and the second light-permeable layer 33). In addition, for example, in the embodiment of the present disclosure, the carrier 31 is made of silicon, and the first light-permeable layer 32 and the second light-permeable layer 33 are made of at least one of germanium and zinc sulfide. However, the constituent material of the optical element 3 is not limited in the present disclosure. Moreover, in the embodiments of the present disclosure, a thickness of the carrier 31 ranges from 0.05 mm to 2 mm, and a thickness of the first light-permeable layer 32 and the second light-permeable layer 33 ranges from 0.01 μm to 50 μm.

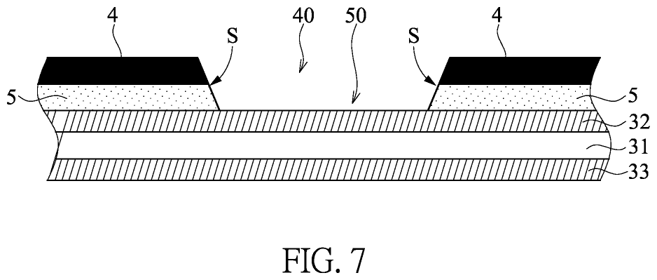

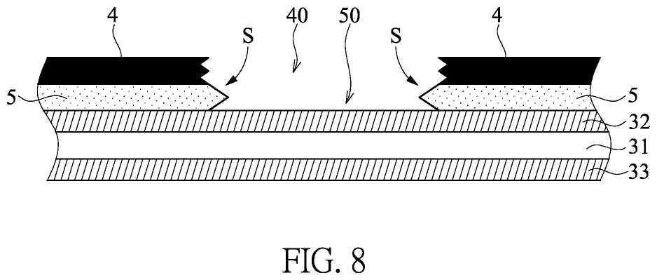

Referring to FIG. 6 to FIG. 8, FIG. 6 to FIG. 8 show different implementations of the optical element 3. The sensing package structure M further includes the reflective layer 5. The reflective layer 5 is disposed between the first blocking layer 4 and the first light-permeable layer 32. The reflective layer 5 has a through hole 50, and the through hole 50 corresponds to and communicates with the first opening 40. For example, the reflective layer 5 is made of gold, silver, aluminum, or composite materials thereof, or multi-layer stack materials thereof, but the material of the reflective layer 5 is not limited in the present disclosure. The reflective layer 5 has a high reflectivity of over 92% and provides a nearly mirror surface, but the present disclosure is not limited thereto. In addition, a thickness of the reflective layer 5 ranges from 0.01 μm to 50 μm. Specifically, the infrared L enters the first opening 40 and the through hole 50, and passes through the first light-permeable layer 32. Then, a part of the infrared L is reflected by the carrier 31 because the carrier 31 has a low transmittance. The reflected part of the infrared L is further reflected by the reflective layer 5. As shown in FIG. 5, this part of the infrared L will be directly absorbed by the first blocking layer 4 if the reflective layer 5 does not exist. In other words, the reflective layer 5 can increase the probability of the infrared L penetrating the optical element 3, and the thermal radiation energy collected by the sensor 2 can be increased, thereby improving the sensing accuracy of the sensor 2. Furthermore, the portion where the first opening 40 is formed on the first blocking layer 4 and a portion where the through hole 50 is formed on the reflective layer 5 jointly form a cross section S. A shape of a contour of the cross section S is not limited in the present disclosure. For example, the cross section S can be a vertical or inclined flat surface. In FIG. 6, the apertures of the first opening 40 and the through hole 50 gradually become wider from outside to inside. In FIG. 7, the apertures of the first opening 40 and the through hole 50 gradually become narrower from inside to outside. In FIG. 8, the cross section S is a rough surface. Through the design of the cross section S, the probability of the infrared L being reflected again by the reflective layer 5 is further increased.

### Second Embodiment

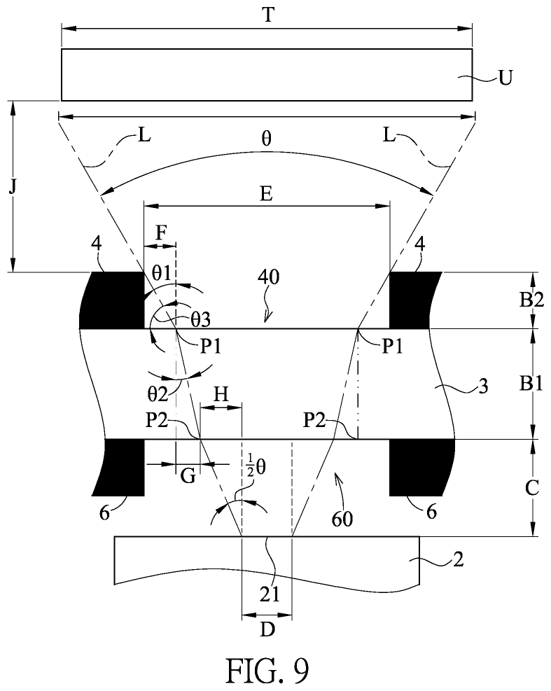

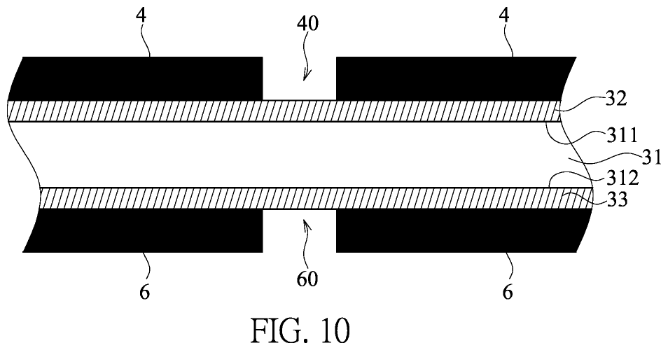

Referring to FIG. 9 and FIG. 10, FIG. 9 is a schematic view showing a detection model of a sensing package structure according to a second embodiment of the present disclosure, and FIG. 10 is a schematic view of an optical element of the sensing package structure according to the second embodiment of the present disclosure. The sensing package structure M in the second embodiment has a structure similar to that of the sensing package structure M in FIG. 1, and the similarities therebetween will not be reiterated herein. The sensing package structure M in the second embodiment further includes a second blocking layer 6 which is disposed on the second light-permeable layer 33. The second blocking layer 6 has a second opening 60, and the second opening 60 corresponds to the first opening 40.

Furthermore, the second opening 60 faces the first opening 40. In other words, a central line of the second opening 60 coincides with a central line of the first opening 40. The aperture of the first opening 40 and an aperture of the second opening 60 can be equal or unequal to each other, and the present disclosure is not limited thereto. In the second embodiment, the aperture of the first opening 40 is equal to the aperture of the second opening 60. In this case, the first opening 40 is the main factor that determines the FOV. Comparing FIG. 3 with FIG. 9, a path of the infrared L in the second embodiment is consistent with a path of the infrared L in the first embodiment because the size of the first opening 40 in FIG. 3 and FIG. 9 remains unchanged. The second blocking layer 6 can secondarily reflect the infrared L which is reflected from a non-sensing region of the sensor 2 to adjust the radiation energy received by the sensing region 21, thereby reducing or increasing signal strength output by the sensor 2.

### Third Embodiment

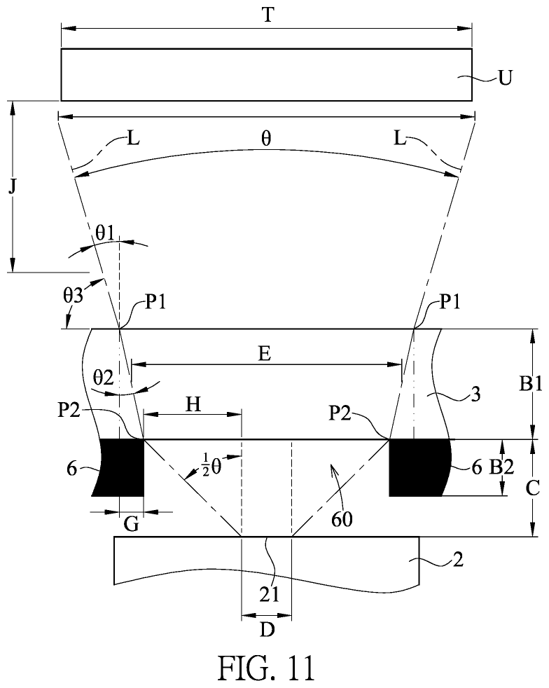

Referring to FIG. 1 and FIG. 11, FIG. 11 is a schematic view showing a detection model of a sensing package structure according to a third embodiment of the present disclosure. The sensing package structure M in the third embodiment has a structure similar to that of the sensing package structure M in FIG. 1, and the similarities therebetween will not be reiterated herein. Comparing FIG. 3 with FIG. 11, the main difference therebetween is as follows: in the third embodiment, the first blocking layer 4 of the sensing package structure M is disposed on the second light-permeable layer 33 of the optical element 3 instead of the first light-permeable layer 32. Therefore, the infrared L will not be blocked by the first blocking layer 4 when the infrared L enters the sensing package structure M from the external environment, and the FOV has a wider range.

In other words, in the sensing package structure M provided by the present disclosure, one blocking layer is provided on one side of the optical element 3 (i.e., the first light-permeable layer 32 or the second light-permeable layer 33), or both sides of the optical element 3 (i.e., the first light-permeable layer 32 and the second light-permeable layer 33) have one blocking layer provided thereon. Comparing with the sensing package structure with double-sided blocking layers (i.e., the sensing package structure M in the second embodiment), the sensing package structure with one-sided blocking layer (i.e., the sensing package structure M in the third embodiment) only needs a smaller aperture to obtain the same FOV. This is because the radiation is restricted only after the radiation is refracted and passes through an optical filter when the blocking layer is not provided on a top side of the optical element 3. In addition, in the third embodiment, the first blocking layer 4 is closer to the sensor 2, such that the structural dimensions inside the sensing package structure M is changed accordingly.

Due to changes in the structural dimensions inside the sensing package structure M, the equation for estimating the structural dimensions inside the sensing package structure M is also adjusted accordingly. For example, the equations (1) and (3) do not need to be adjusted, but the aperture E of the first opening 40 will be adjusted from meeting the equation (4) to meeting the following relation:

$$E = 2 H + D . \qquad equation ( 6 )$$

The detection distance J of the sensing package structure M will be adjusted from meeting the equation (5) to meeting the following relation:

$$J = ( T - E - 2 G ) / ( 2 \times tan ( θ1 ) ) . \qquad equation ( 7 )$$

### Fourth Embodiment

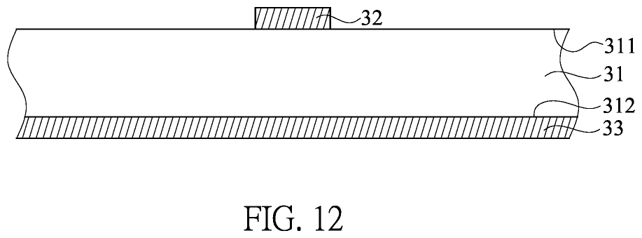

Referring to FIG. 1 and FIG. 12, FIG. 12 is a schematic view of an optical element of a sensing package structure according to a fourth embodiment of the present disclosure. The sensing package structure M in the fourth embodiment has a structure similar to that of the sensing package structure M in FIG. 1. As shown in FIG. 1, the sensing package structure M includes a substrate 1, a sensor 2, and an optical element 3. The sensor 2 is disposed on the substrate 1. The sensor 2 has a sensing region 21 for receiving an infrared. The optical element 3 is disposed in the substrate 1 and is located above the sensor 2. The optical element 3 includes a carrier 31, a first light-permeable layer 32, and a second light-permeable layer 33. The carrier 31 has a first surface 311 and a second surface 312 that are opposite to each other. The first light-permeable layer 32 is disposed on the first surface 311, and the second light-permeable layer 33 is disposed on the second surface 312. For example, the carrier 31 is made of silicon, and the first light-permeable layer 32 and the second light-permeable layer 33 are made of at least one of germanium and zinc sulfide.

Comparing the sensing package structure in the fourth embodiment with the sensing package structure in the first embodiment, the main difference is as follows: the sensing package structure M in the fourth embodiment has no blocking layer, and a width of the first light-permeable layer 32 is smaller than a width of the second light-permeable layer 33. The first light-permeable layer 32 is located at a central position of the carrier 31 and corresponds to the sensing region 21 of the sensor 2, and the width of the first light-permeable layer 32 is greater than the width of the sensing region 21. When an infrared generated by a to-be-detected object enters the sensing package structure, a part of the infrared enters the first light-permeable layer 32 and passes through the optical element 3, and another part of the infrared directly enters and is blocked at the first surface 311 of the carrier 31 because the first light-permeable layer 32 has high transmittance and the carrier 31 has low transmittance. In addition, the sensing package structure in the fourth embodiment is more suitable for application in the infrared having a wavelength range of from 5.5 μm to 14 μm.

### Beneficial Effects of the Embodiments

In conclusion, the overall height of the sensing package structure provided by the present disclosure can be reduced by replacing the metal cover of the existing temperature sensor with the first blocking layer 4 having the first opening 40 formed thereon for light to pass through. Furthermore, the metal cover has high thermal conductivity and is easily affected by the temperature of the external environment. In comparison, the sensing package structure provided by the present disclosure does not need a metal cover. In the present disclosure, a blocking layer is directly disposed on the optical element 3, such that the sensing package structure is less likely to be affected by the temperature of the external environment.

Furthermore, the FOV can be adjusted by changing internal structure dimensions of the sensing package structure provided by the present disclosure, so as to obtain an appropriate detection distance. Alternatively, the required FOV can be calculated through a predetermined detection distance and the internal structure size can be adjusted correspondingly.

Moreover, the position and the size of the first light-permeable layer 32 of the sensing package structure can be further adjusted such that the width of the first light-permeable layer 32 is smaller than the width of the second light-permeable layer 33. In addition, the first light-permeable layer 32 is disposed in the middle position of the carrier 31 and corresponds to the sensing region 21 of the sensor 2. Therefore, when the sensing package structure senses the temperature, the infrared concentrates and passes through the optical element 3 from the first light-permeable layer 32, and is received by the sensor 2. In this way, the metal cover of the existing temperature sensor can also be replaced such that the effect of reducing the overall height of the sensing package structure can be achieved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A sensing package structure, comprising:
a substrate;
a sensor disposed on the substrate;
an optical element disposed above the sensor; and
a first blocking layer disposed on the optical element, wherein the first blocking layer has a first opening, and an aperture of the first opening is greater than a thickness of the optical element; wherein a radiation that enters the first opening passes through the optical element and is received by the sensor.

2. The sensing package structure according to claim 1, wherein the optical element includes:
a carrier having a first surface and a second surface that are opposite to each other;
a first light-permeable layer disposed on the first surface; and
a second light-permeable layer disposed on the second surface.

3. The sensing package structure according to claim 2, wherein the carrier is made of silicon, and the first light-permeable layer and the second light-permeable layer are made of at least one of germanium and zinc sulfide.

4. The sensing package structure according to claim 2, wherein the first blocking layer is disposed on the first light-permeable layer or the second light-permeable layer.

5. The sensing package structure according to claim 3, further comprising a reflective layer having a through hole, wherein, when the first blocking layer is disposed on the first light-permeable layer, the reflective layer is disposed between the first blocking layer and the first light-permeable layer, and the through hole corresponds to and communicates with the first opening.

6. The sensing package structure according to claim 4, wherein a portion where the first opening is formed on the first blocking layer and a portion where the through hole is formed on the reflective layer jointly form a cross section, and the cross section has a rough surface.

7. The sensing package structure according to claim 4, further comprising a second blocking layer having a second opening, wherein, when the first blocking layer is disposed on the first light-permeable layer, the second blocking layer is disposed on the second light-permeable layer, and the second opening corresponds to the first opening.

8. The sensing package structure according to claim 1, wherein the sensor has a sensing angle, the radiation enters the optical element at an incident angle and passes through the optical element at a refraction angle, and the sensing angle is twice the incident angle.

9. The sensing package structure according to claim 8, wherein an incident position where the radiation enters the optical element is separated from an exit position where the radiation is emitted from the optical element by a first horizontal distance, and the first horizontal distance meets the following relation:
$$G = B 1 \times tan ( θ2 ) ;$$
wherein G is the first horizontal distance, B1 is the thickness of the optical element, and θ2 is the refraction angle.

10. The sensing package structure according to claim 9, wherein the sensor has a sensing region, the sensing region is configured to receive the radiation, the sensing region faces the first opening, the exit position is separated from the sensing region by a second horizontal distance, the optical element is separated from the sensing region by a predetermined vertical distance, and the second horizontal distance and the predetermined vertical distance meet the following relation:
$$H = C \times tan ( θ / 2 ) ;$$
wherein H is the second horizontal distance, C is the predetermined vertical distance, and θ is the sensing angle.

11. The sensing package structure according to claim 10, wherein a portion where the first opening is formed on the first blocking layer forms a cross section, the cross section is separated from the incident position by a third horizontal distance, and the third horizontal distance meets the following relation:
$$F = B 2 / tan ( θ3 ) ;$$
wherein F is the third horizontal distance, B2 is a thickness of the first blocking layer, and θ3 is an alternate interior angle of the incident angle.

12. The sensing package structure according to claim 11, wherein the aperture of the first opening meets the following relation:
$$E = 2 F + 2 G + 2 H + D ;$$
wherein E is the aperture, F is the third horizontal distance, G is the first horizontal distance, H is the second horizontal distance, and D is a width of the sensing region.

13. The sensing package structure according to claim 10, wherein the aperture of the first opening meets the following relation:
$$E = 2 H + D ;$$
wherein E is the aperture, H is the second horizontal distance, and D is a width of the sensing region.

14. The sensing package structure according to claim 1, further comprising a wall disposed on the substrate, wherein the wall and the substrate jointly form a cavity, the sensor is disposed in the cavity, and the optical element is disposed on the wall.

15. The sensing package structure according to claim 1, further comprising an integrated circuit component disposed on the substrate, wherein the sensing element is disposed on the integrated circuit component or adjacent to the integrated circuit component.

16. The sensing package structure according to claim 1, wherein the sensing element is used to sense a thermal radiation ranges in an infrared band.

17. The sensing package structure according to claim 16, wherein the first blocking layer is made of an opaque material.

18. A sensing package structure, comprising:
a substrate;
a sensor disposed on the substrate, wherein the sensor has a sensing region for receiving an infrared; and
an optical element disposed above the sensor, wherein the optical element includes:
a carrier having a first surface and a second surface that are opposite to each other;
a first light-permeable layer disposed on the first surface; and
a second light-permeable layer disposed on the second surface;
wherein a width of the first light-permeable layer is smaller than a width of the second light-permeable layer, the first light-permeable layer corresponds to the sensing region, and the width of the first light-permeable layer is greater than a width of the sensing region.

19. The sensing package structure according to claim 18, wherein the carrier is made of silicon, and the first light-permeable layer and the second light-permeable layer are made of at least one of germanium and zinc sulfide.
